(19) United States
(12) Patent Application Publication
(10) Pub. No.: US 2025/0074054 A1
(43) Pub. Date: Mar. 6, 2025

(54) LAMINATED SUBSTRATE, MANUFACTURING METHOD THEREFOR, AND LIQUID DISCHARGE HEAD

(71) Applicant: CANON KABUSHIKI KAISHA, Tokyo (JP)

(72) Inventors: YUKI KOMORI, Tokyo (JP); SOUTA TAKEUCHI, Kanagawa (JP); MASATAKA KATO, Kanagawa (JP)

(21) Appl. No.: 18/814,025

(22) Filed: Aug. 23, 2024

(30) Foreign Application Priority Data
Aug. 28, 2023 (JP) 2023-138348

(51) Int. Cl. B41J 2/14; H01L 21/02; H01L 21/311

(52) U.S. Cl. CPC B41J 2/14201; H01L 21/02164; H01L 21/31116

(57) ABSTRACT

A laminated substrate includes a silicon substrate, and a silicon oxide film laminated to the silicon substrate, wherein the silicon oxide film has a through hole penetrating in a thickness direction, wherein the silicon substrate has a hole communicating with the through hole, wherein the hole includes a first portion adjacent to the through hole and a second portion adjacent to the first portion on an opposite side of the through hole, wherein the first portion includes a plurality of first recesses whose width changes cyclically in the thickness direction, wherein the second portion includes a plurality of second recesses whose width changes cyclically in the thickness direction, and wherein a maximum value of the width of the first recesses is smaller than a maximum value of the width of the second recesses.

### BACKGROUND

### Field

The present disclosure relates to a laminated substrate, a manufacturing method therefor, and a liquid discharge head.

### Description of the Related Art

As a liquid discharge head used in an inkjet printer or the like, Japanese Patent No. 7119943 discusses a liquid discharge head including a liquid discharge flow path formed in a laminated substrate of a silicon substrate and a silicon oxide film. International Publication No. 2016/158917 discusses formation of a liquid discharge flow path in a silicon substrate using dry etching, namely, the Bosch process, in which isotropic etching, formation of a sidewall protective film, and anisotropic etching are repeated.

In forming a through hole penetrating a silicon oxide film in the laminated substrate discussed in Japanese Patent No. 7119943 and further forming a hole that communicates with the through hole in the silicon substrate, applying the Bosch process discussed in International Publication No. 2016/158917 is considered. At this time, a reaction product generated by etching the silicon oxide film may be deposited at the bottom of the through hole in the silicon oxide film. The deposited reaction product will be removed by the Bosch process, but the thickness of the reaction product varies in a wafer plane. For this reason, at a boundary between the silicon substrate and the silicon oxide film, the width of the hole in the silicon substrate may vary in the wafer plane.

### SUMMARY

The present disclosure is directed to providing a laminated substrate with which it is possible to suppress variations in the width of holes in a silicon substrate at the boundary between a silicon substrate and a silicon oxide film.

According to an aspect of the present disclosure, a laminated substrate includes a silicon substrate, and a silicon oxide film laminated to the silicon substrate, wherein the silicon oxide film has a through hole penetrating in a thickness direction, wherein the silicon substrate has a hole communicating with the through hole, wherein the hole includes a first portion adjacent to the through hole and a second portion adjacent to the first portion on an opposite side of the through hole, wherein the first portion includes a plurality of first recesses whose width changes cyclically in the thickness direction, wherein the second portion includes a plurality of second recesses whose width changes cyclically in the thickness direction, and wherein a maximum value of the width of the first recesses is smaller than a maximum value of the width of the second recesses.

Further features of the present disclosure will become apparent from the following description of exemplary embodiments with reference to the attached drawings.

### BRIEF DESCRIPTION OF THE DRAWINGS

FIG. 1 is a partial cross-sectional view of a liquid discharge head according to an exemplary embodiment of the present disclosure.

FIG. 2A is a partial cross-sectional view of a laminated substrate formed on an outer peripheral side of a wafer, and FIG. 2B is a partial cross-sectional view of the laminated substrate formed on a center side of the wafer.

FIGS. 3A to 3F are cross-sectional diagrams illustrating a manufacturing method for a laminated substrate according to a comparative example: FIG. 3A is a cross-sectional view of the laminated substrate in which a silicon substrate and a silicon oxide film are laminated; FIG. 3B is a cross-sectional view of the laminated substrate after forming a photoresist; FIG. 3C is a cross-sectional view of the laminated substrate in which a first through hole is formed; FIG. 3D is a cross-sectional view of the laminated substrate in which a hole to be a second through hole is formed on the outer peripheral side of a wafer; FIG. 3E is a cross-sectional view of the laminated substrate in which a hole to be the second through hole is formed on the center side of the wafer; and FIG. 3F is a cross-sectional view of the laminated substrate in which the second through hole is formed.

FIG. 4 is a schematic view of an apparatus used for etching.

FIG. 5A is a cross-sectional view of the outer peripheral side of the wafer of the laminated substrate according to the comparative example, and FIG. 5B is a cross-sectional view of the center side of the wafer of the laminated substrate according to the comparative example.

FIGS. 6A to 6F are diagrams illustrating a general manufacturing process for the laminated substrate of the liquid discharge head illustrated in FIG. 1. FIG. 6A is a cross-sectional view of the laminated substrate in which a silicon substrate and a silicon oxide film are laminated; FIG. 6B is a cross-sectional view of the laminated substrate after forming a photoresist; FIG. 6C is a cross-sectional view of the laminated substrate in which a first through hole is formed; FIG. 6D is a cross-sectional view of the laminated substrate in which a hole to be a second through hole is formed on the outer peripheral side of a wafer; FIG. 6E is a cross-sectional view of the laminated substrate in which a hole to be the second through hole is formed on the center side of the wafer; and FIG. 6F is a cross-sectional view of the laminated substrate in which the second through hole is formed.

### DESCRIPTION OF THE EMBODIMENTS

Hereinafter, a laminated substrate according to an exemplary embodiment of the present disclosure will be described with reference to the drawings. The exemplary embodiment described below is an example of a technically preferred form of the present disclosure, and the present disclosure is not limited to the exemplary embodiment. Each drawing is a schematic diagram, and the shape, size, number, and the like of each part are merely examples. The laminated substrate according to the exemplary embodiment described below is applied to a liquid discharge head using a piezoelectric element, but can also be applied to a liquid discharge head using a heating resistance element or an electrothermal converting element.

Liquid discharged is not limited to ink as long as the liquid can be discharged from the liquid discharge head.

In the following descriptions and the drawings, a thickness direction X refers to the direction in which a silicon substrate and a silicon oxide film are laminated. The thickness and depth refer to dimensions in the thickness direction X or a thickness direction of a wafer. Any direction perpendicular to the thickness direction X will be called a radial direction R. The width refers to a dimension in the radial direction R, and is equal to the diameter in the case of a hole or through hole with a circular cross section.

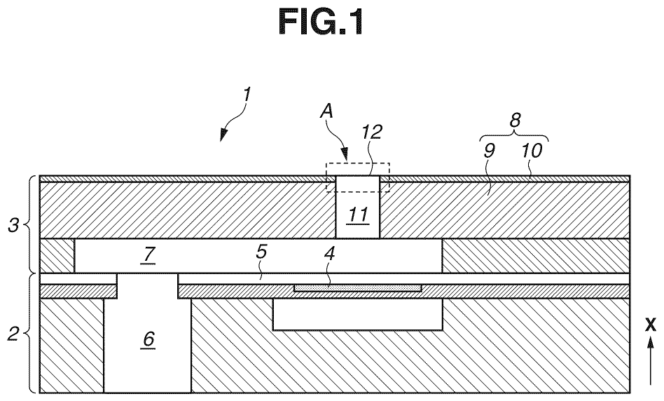

FIG. 1 is a partial cross-sectional view of a liquid discharge head 1. The liquid discharge head 1 includes an actuator substrate 2 and a discharge port formation substrate 3 bonded to the actuator substrate 2. The actuator substrate 2 includes a piezoelectric element 4, a vibration film 5 laminated to the piezoelectric element 4, and a liquid supply path 6 that penetrates the actuator substrate 2 in the thickness direction X. The piezoelectric element 4 is an energy generation element that imparts energy to ink to be discharged. A pressure chamber 7 is formed between the vibration film 5 and the discharge port formation substrate 3, and the ink fills the pressure chamber 7 through the liquid supply path 6.

The discharge port formation substrate 3 includes a laminated substrate 8 in which a silicon substrate 9 and a silicon oxide film 10 are laminated. The laminated substrate 8 is fabricated by a wafer process. The laminated substrate 8 includes a liquid discharge flow path 11 that penetrates the discharge port formation substrate 3 in the thickness direction X. A first through hole 12 from which the ink is discharged is formed on the most downstream side in the discharge direction of the liquid discharge flow path 11. When a drive voltage with a pull-push-pull waveform is applied to the piezoelectric element 4, the vibration film 5 vibrates, and the pressure chamber 7 repeatedly expands and contracts. The ink in the pressure chamber 7 is pressurized, and the ink is discharged through the liquid discharge flow path 11.

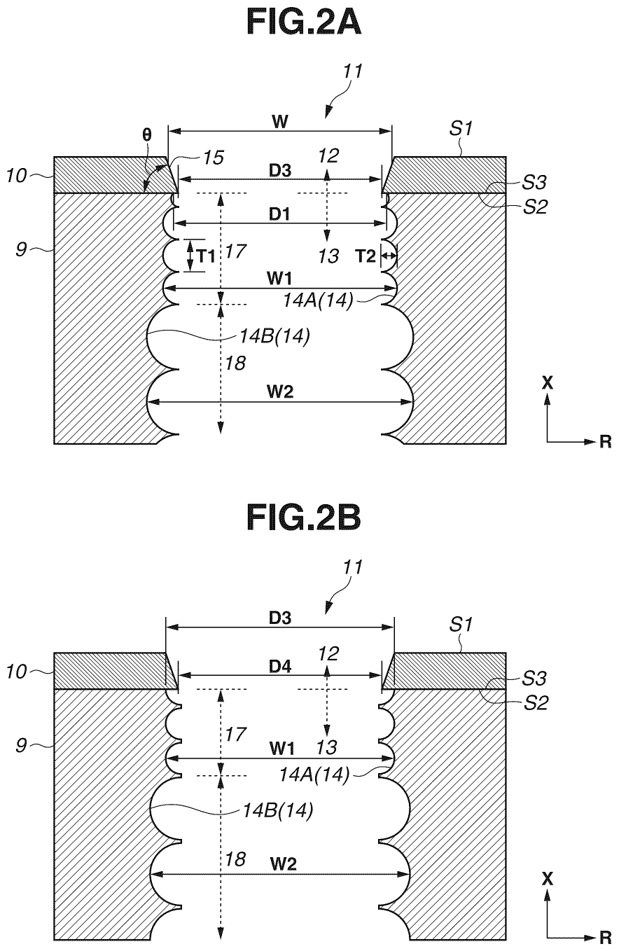

FIGS. 2A and 2B are enlarged views of a part A in FIG. 1, and illustrate a partial cross section of the laminated substrate 8. FIG. 2A is a cross-sectional view of the laminated substrate 8 formed on the outer peripheral side of the wafer, and FIG. 2B is a cross-sectional view of the laminated substrate 8 formed on the center side of the wafer. The laminated substrate 8 formed on the outer peripheral side of the wafer and the laminated substrate 8 formed on the center side of the wafer are slightly different in configuration, and a reason for the difference will be described below. The silicon oxide film 10 has a back surface (hereinafter referred to as a first surface S1) of a contact surface in contact with the silicon substrate 9, and the contact surface in contact with the silicon substrate 9 (hereinafter referred to as a second surface S2). The silicon substrate 9 has a contact surface in contact with the silicon oxide film 10 (hereinafter referred to as a third surface S3). The first to third surfaces S1 to S3 are parallel to one another.

The silicon oxide film 10 has the first through hole 12 that penetrates in the thickness direction X, and the silicon substrate 9 has a second through hole 13 that penetrates in the thickness direction X and communicates with the first through hole 12. The first through hole 12 and the second through hole 13 form the liquid discharge flow path 11. Central axes of the first through hole 12 and second through hole 13 are substantially concentric. Depending on use application of the laminated substrate 8, instead of the second through hole 13, the silicon substrate 9 may be provided with a hole that communicates with the first through hole 12 and terminates midway in the thickness direction X.

The first through hole 12 can be formed by dry etching, such as reactive ion etching (RIE). Since a combination of the silicon oxide film 10 and RIE allows highly anisotropic etching in the thickness direction X, large asperities are not formed on the sidewall of the first through hole 12. The second through hole 13 is formed by dry etching (Bosch process) in which isotropic etching, formation of a sidewall protective film, and anisotropic etching are repeated, so that an amount of side etching, i.e., an amount of etching in the radial direction R, is larger than that of the first through hole 12. As a result, a cyclic recess structure in which a plurality of recesses 14 called scallops is continuously arranged in the thickness direction X is formed on a side surface of the second through hole 13. The recesses 14 are annular grooves extending circumferentially on the side surface of the second through hole 13, and each have an approximately semicircular cross-sectional shape.

A width W of the first through hole 12 monotonically decreases from the first surface S1 toward the second surface S2.

The silicon oxide film 10 is located outside the silicon substrate 9, i.e., downstream in the ink discharge direction, so that at least the downstream side of the liquid discharge flow path 11 has a relatively smooth tapered side surface. Since the first through hole 12 is formed in almost the same shape in any region of the wafer, variation in the diameter of the first through hole 12 in the wafer can be suppressed. When the pressure chamber 7 expands, the ink is drawn in, and a meniscus is generated in the first through hole 12 of the silicon oxide film 10. Since the first through hole 12 has a tapered shape, the meniscus is stably formed near the boundary between the first through hole 12 and the second through hole 13, as compared to a case where the first through hole 12 has a constant cross section. In order to have the meniscus stably formed, it is preferable that an average inclination angle θ of a side surface 15 of the first through hole 12 with respect to the second surface S2 be 60° or more and less than 90°.

### Comparative Example

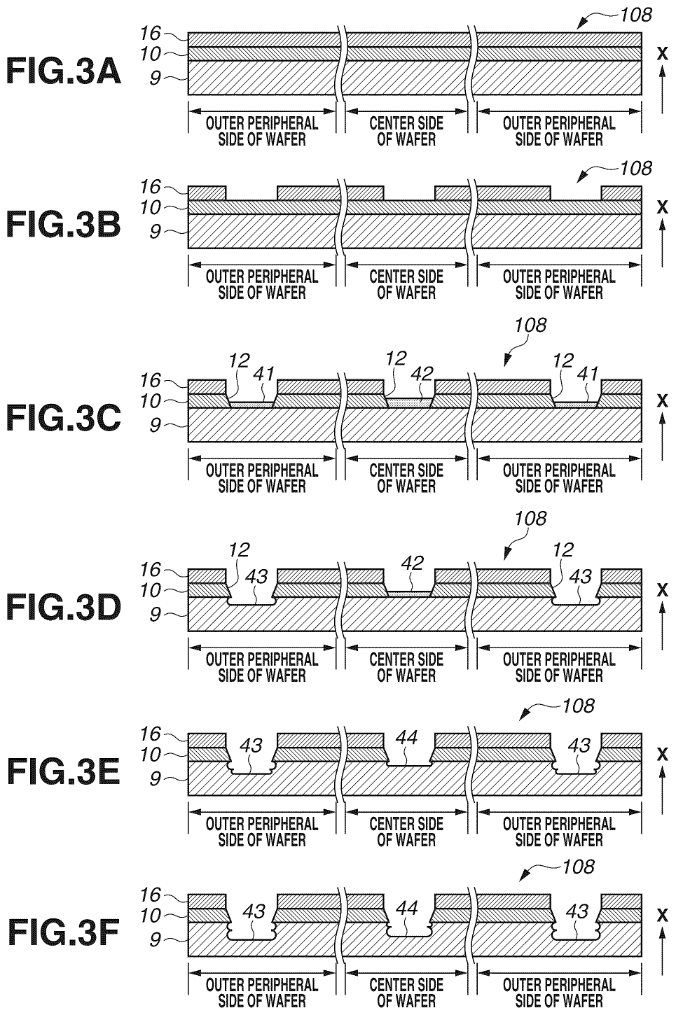

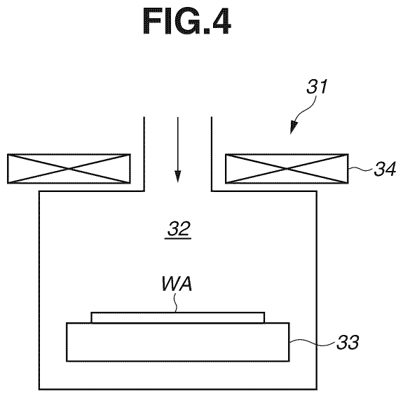

In order to explain an effect of the present exemplary embodiment, a configuration and a manufacturing method of a laminated substrate 108 according to a comparative example will be described with reference to FIGS. 3A to 5B. FIGS. 3A to 3F illustrate a general manufacturing process of the laminated substrate 108 according to the comparative example. First, as illustrated in FIG. 3A, the laminated substrate 108 is prepared in which a silicon substrate 9 and a silicon oxide film 10 are laminated. Next, in order to form first through holes 12 in the silicon oxide film 10, a photoresist 16 is applied as illustrated in FIG. 3B, and a pattern of the first through holes 12 is formed by photolithography. Then, as illustrated in FIG. 3C, the silicon oxide film 10 is etched via the photoresist 16 to form the first through holes 12. FIG. 4 illustrates an outline of an etching apparatus 31 used for the comparative example. A wafer WA is carried into a chamber 32 and is adsorbed and held on a sample stage 33. Microwaves are supplied to the chamber 32, and a gas inside the chamber 32 is excited by a magnetic field generated by the microwaves and a coil 34, and plasma is formed in a space above the wafer WA. High-frequency bias power is applied to the sample stage 33, and ions in the plasma are incident on the wafer WA, thereby the wafer WA is etched.

When the silicon oxide film 10 is etched, reaction by-products 41 and 42 are generated. The reaction by-products 41 and 42 enter each of the first through holes 12 and are deposited at the bottom of each first through hole 12, i.e., on the upper surface of the silicon substrate 9. The reaction by-product 41 on the outer peripheral side of the wafer and the reaction by-product 42 on the center side of the wafer have the same components, but the reaction by-product 42 on the center side of the wafer is larger in film thickness than the reaction by-product 41 on the outer peripheral side of the wafer. The difference in film thickness occurs because a gas distribution in the chamber 32 is different between a center part and an outer peripheral part of the wafer.

Next, as illustrated in FIG. 3D, the silicon substrate 9 is etched via the photoresist 16 and the first through holes 12 to form holes 43 and 44 to be second through holes 13. The etching is performed by the Bosch process. Since the reaction by-products 41 and 42 are deposited in the first through holes 12, first few cycles of the Bosch process are used to remove the reaction by-products 41 and 42 that are etching inhibitors, and do not contribute to the etching of the silicon substrate 9. The etching of the silicon substrate 9 is started from a first through hole 12 from which the reaction by-product 41 or 42 has been removed. Since the reaction by-product 41 is removed from each of the first through holes 12 on the outer peripheral side of the wafer before the reaction by-product 42 is removed from the first through hole 12 on the center side of the wafer, formation of the hole 43 on the outer peripheral side of the wafer is started at a stage where the reaction by-product 42 on the center side of the wafer still remains.

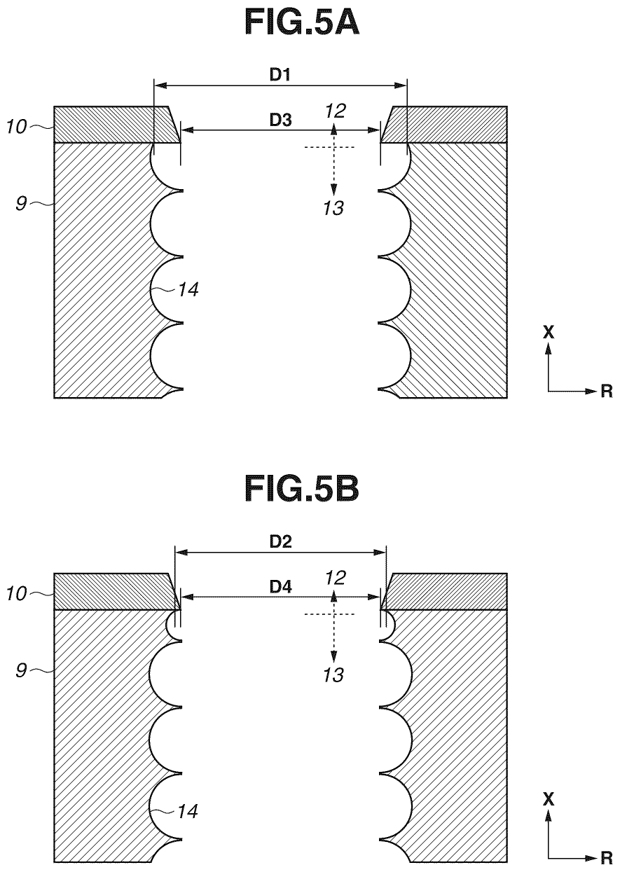

As illustrated in FIG. 3E, the reaction by-product 42 on the center side of the wafer is removed, and formation of the hole 44 on the center side of the wafer to be the second through hole 13 is started. The formation of the hole 44 on the center side of the wafer is started in the middle of a first cycle that contributes to the etching of the silicon substrate 9, so that the recess 14 near the boundary with the silicon oxide film 10 is smaller than the recess 14 of the hole 43 on the outer peripheral side of the wafer (see FIGS. 5A and 5B). Then, as illustrated in FIG. 3F, the Bosch process is continued, and the holes 43 and 44 in the silicon substrate 9 become deeper. However, since a protective film is formed on the sidewall in the Bosch process, the holes 43 and 44 formed in the first cycle, i.e., the holes 43 and 44 near the boundary with the silicon oxide film 10, are hardly changed in shape. Although not illustrated, the Bosch process is further continued to form the second through holes 13 in the silicon substrate 9.

FIGS. 5A and 5B illustrate cross sections of the first through hole 12 and second through hole 13 in the laminated substrate 108 according to the comparative example. FIG. 5A is a cross-sectional view of the first through hole 12 and the second through hole 13 on the outer peripheral side of the wafer, and FIG. 5B is a cross-sectional view of the first through hole 12 and the second through hole 13 on the center side of the wafer. As described above, the recesses 14 are formed on the side surface of the second through hole 13 by the Bosch process. The dimensions thereof will be defined as follows.
D1: Width of the recess 14 on the outer peripheral side of the wafer at the boundary with the silicon oxide film 10
D2: Width of the recess 14 on the center side of the wafer at the boundary with the silicon oxide film 10
D3: Width of the first through hole 12 on the outer peripheral side of the wafer at the boundary with the silicon substrate 9
D4: Width of the first through hole 12 on the center side of the wafer at the boundary with the silicon substrate 9

In the comparative example, D1>D2. This is because the size of the recess 14 adjacent to the silicon oxide film 10 differs between the center side of the wafer and the outer peripheral side of the wafer. On the other hand, the etching of the silicon oxide film 10 progresses in the same manner on the center side of the wafer and the outer peripheral side of the wafer. Thus, D3 and D4 are substantially equal. There is almost no difference between D2 and D4 on the center side of the wafer, and there is a difference between D1 and D3 on the outer peripheral side of the wafer. In the actual Bosch process, the difference between D1 and D3 reaches about several micrometers (m), so a flow resistance occurs in the liquid discharge flow path 11 during discharge. In addition, the flow resistance in the liquid discharge flow path 11 varies between the center side of the wafer and the outer peripheral side of the wafer.

In the comparative example, a new cycle of the Bosch process is started at a timing when the reaction by-product 41 on the outer peripheral side of the wafer is removed, so D1>D2. However, the timing when the formation of the second through hole 13 in the silicon substrate 9 is started depends on a relationship between the thickness of the reaction by-product 41 or 42 and the amount of removal per unit time. For example, depending on the thickness of the reaction by-product 41 or 42, the new cycle of the Bosch process may be started at a timing when the reaction by-product 42 on the center side of the wafer is just removed. In such a case, there is a possibility that D1<D2. Therefore, although the size relationship among D1 to D4 is not limited to the relationship illustrated in FIGS. 5A and 5B, the reaction by-products 41 and 42 are different in thickness between the center side of the wafer and the outer peripheral side of the wafer, so that the difference between D1 and D3 and the difference between D2 and D4 are different between the center side of the wafer and the outer peripheral side of the wafer.

### (General Manufacturing Process of Laminated Substrate 8 in Present Exemplary Embodiment)

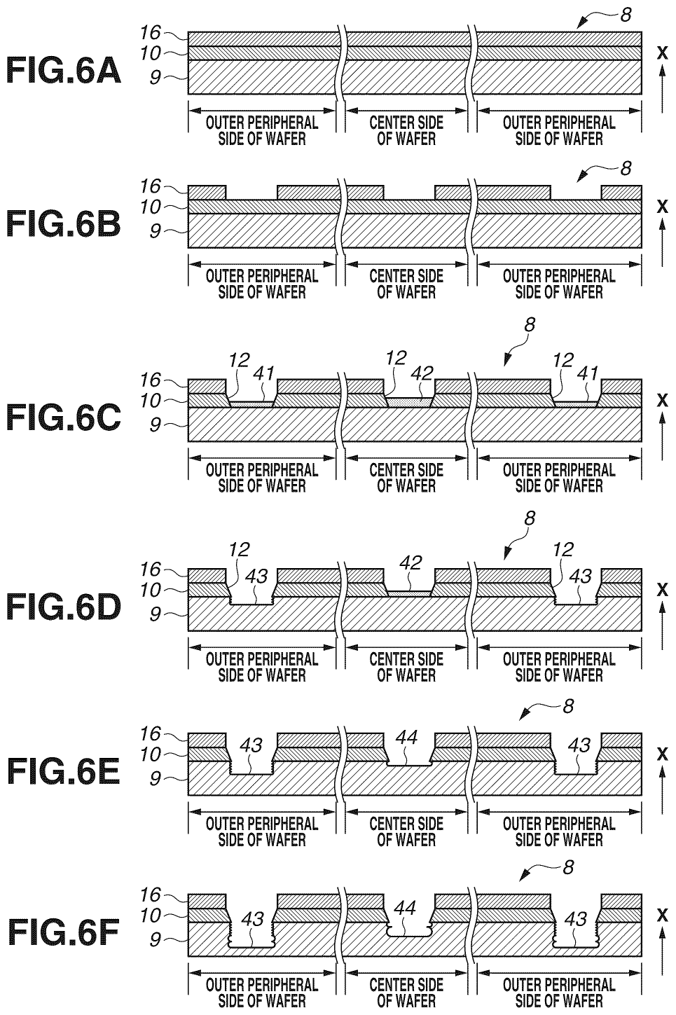

A general manufacturing process of the laminated substrate 8 according to the present exemplary embodiment will be described with reference to FIGS. 2A and 2B and 6A to 6F. The etching apparatus 31 used in the present exemplary embodiment is the same as that illustrated in FIG. 4. Processes illustrated in FIGS. 6A to 6C are the same as those of the comparative example illustrated in FIGS. 3A to 3C, and therefore descriptions thereof will be omitted. As in the comparative example, the reaction by-product 42 on the center side of the wafer is larger in film thickness than the reaction by-product 41 on the outer peripheral side of the wafer.

In processes illustrated in FIG. 6D to 6F, the second through holes 13 are formed so as to penetrate the silicon substrate 9 in the thickness direction X. First, as illustrated in FIG. 6D, the silicon substrate 9 is etched via the photoresist 16 and the first through holes 12 to form the holes 43 to be the second through holes 13. The etching is performed by the Bosch process. Since the reaction by-products 41 and 42 are deposited in the first through holes 12, the first few cycles of the Bosch process are used to remove the reaction by-products 41 and 42 that are etching inhibitors, and do not contribute to the etching of the silicon substrate 9. Since the reaction by-product 41 is removed from each of the first through holes 12 on the outer peripheral side of the wafer before the reaction by-product 42 is removed from the first through holes 12 on the center side of the wafer, the formation of the hole 43 on the outer peripheral side of the wafer is started at the stage where the reaction by-product 42 on the center side of the wafer still remains. The above processes are the same as those of the comparative example.

In the present exemplary embodiment, etching conditions are changed between the first few cycles (hereinafter referred to as initial cycles) of the Bosch process for forming the second through holes 13 and the subsequent remaining cycles (hereinafter referred to as final cycles). FIGS. 6D and 6E illustrate the initial cycles, and FIG. 6F illustrates the final cycles. A portion of each of the holes 43 and 44 formed in the initial cycles will be referred to as a first portion 17, and a portion of each of the holes 43 and 44 formed in the final cycles will be referred to as a second portion 18 (see FIGS. 2A and 2B). In other words, the process of forming each of the holes 43 and 44 includes a process of forming the first portion 17 adjacent to the first through hole 12, and a process of forming the second portion 18 adjacent to the first portion 17 on the opposite side of the first through hole 12 after forming the first portion 17.

In the initial cycle, the amount of silicon etching per unit time is reduced as compared to that in the final cycle. In order to reduce the amount of silicon etching per unit time, at least one of the following measures may be changed: reducing the time for dry etching per cycle, reducing the output of the coil 34, and decreasing the pressure in the chamber 32, as compared to those in the final cycle. As illustrated in FIGS. 6D and 6E, the initial cycle continues until the reaction by-product 42 on the center side of the wafer is removed and the formation of the hole 44 on the center side of the wafer is started. The formation of the holes 43 and 44 is started first from the outer peripheral side of the wafer, and the small recesses 14 are formed on the side surfaces of the holes 43. On the center side of the wafer, the formation of the holes 44 is started after that on the outer peripheral side of the wafer, and the small recesses 14 are similarly formed on the side surfaces of the hole 44. The timing of transition from the initial cycle to the final cycle can be calculated in advance from the initial thickness of the reaction by-product 42 on the center side of the wafer and the amount of the reaction by-product 42 removed per cycle in the initial cycle. The initial thickness of the reaction by-product 42 can be obtained by testing.

Next, as illustrated in FIG. 6F, the Bosch process is continued in the final cycle in which the amount of silicon etching per unit time is increased, thereby to form the second through holes 13 in the silicon substrate 9. After the reaction by-products 41 and 42 are removed from the entire wafer, the final cycle in which the amount of silicon etching per unit time is increased is performed, thereby the time required to form the second through holes 13 can be reduced. When the second through holes 13 are formed in the entire wafer, the final cycle is ended.

FIGS. 2A and 2B illustrate cross sections of the first through hole 12 and the second through hole 13 formed by the above process. As described above, the second through hole 13 includes the first portion 17 adjacent to the first through hole 12, and the second portion 18 adjacent to the first portion 17 on the opposite side of the first through hole 12. The first portion 17 has a plurality of first recesses 14A whose width changes cyclically in the thickness direction X. The second portion 18 has a plurality of second recesses 14B whose width changes cyclically in the thickness direction X. A maximum value W1 of the width of the first recesses 14A is smaller than a maximum value W2 of the width of the second recesses 14B. According to the present exemplary embodiment, even if the reaction by-products 41 and 42 are present, D1 and D2 have substantially the same value over the entire wafer, and therefore differences between D1 and D3 and between D2 and D4 are also substantially constant over the entire wafer, so that the variation in the flow resistance of the liquid discharge flow path 11 can be suppressed. In addition, since the period during which the initial cycle is performed is limited, the overall processing time does not increase significantly as compared to the comparative example.

### Example

The present disclosure will be described in more detail with reference to an example. In the example, the discharge port formation substrate 3 illustrated in FIGS. 2A and 2B was produced. The manufacturing process was the same as that illustrated in FIGS. 6A to 6F. First, as illustrated in FIG. 6A, a wafer was prepared in which the silicon oxide film 10 with a thickness of 0.5 m was laminated to the surface of the silicon substrate 9 with a thickness of 20 m. In order to ensure the strength of the wafer during the process, the thickness of the wafer was set to 625 m except for the portion to be processed. Next, as illustrated in FIG. 6B, the photoresist 16 was applied to the silicon oxide film 10 by a thickness of 15 μm, and an opening was formed in the photoresist 16 by irradiation with ultraviolet light and development. The opening had the shape of a circle with a diameter of 30 m as viewed from the thickness direction X.

Next, as illustrated in FIG. 6C, the silicon oxide film 10 was etched by RIE to form the first through holes 12. A mixed gas of C₄F₈ gas, CF₄ gas, and Ar gas was used as an etching gas. The gas pressure was set to 0.3 Pa, the gas flow rate was set to 500 seem, the output of the coil 34 was set to 1500 W, and the platen output was set to 400 W. An angle θ between the side surface 15 of the first through hole 12 and the contact surface (second surface S2) of the silicon oxide film 10 in contact with the silicon substrate 9 was about 80°. At the bottom of each of the first through holes 12, the reaction by-product 41 with a thickness of 50 nm was deposited on the outer peripheral side of the wafer, and the reaction by-product 42 with a thickness of 60 nm was deposited on the center side of the wafer.

Next, as illustrated in FIG. 6D, the silicon substrate 9 was etched via the opening in the photoresist 16 and the first through holes 12 by the Bosch process using sulfur hexafluoride (SF₆), and the first portions 17 of the second through holes 13 were formed in the silicon substrate 9 on the outer peripheral side of the wafer. As the etching conditions, the output of the coil 34 was set to 2000 W and the time for etching was set to 0.6 seconds. The Bosch process was performed a plurality of times to remove the reaction by-product 41 on the outer peripheral side of the wafer. Then, the etching of the silicon substrate 9 was started on the outer peripheral side of the wafer to form the first portions 17 having the first recesses 14A with a dimension T1 of 0.4 μm in the thickness direction X. Before the formation of the first portions 17 on the outer peripheral side of the wafer was started, a processing time equivalent to a depth of 2.4 μm of the silicon substrate 9 was consumed to remove the reaction by-product 41 with a thickness of 50 nm on the outer peripheral side of the wafer. During this time, the reaction by-product 42 on the center side of the wafer was also removed, but not completely removed.

Next, as illustrated in FIG. 6E, the first portions 17 of the second through holes 13 were formed on the center side of the wafer by the Bosch process under the same etching conditions as in FIG. 6D. Before the formation of the first portions 17 on the center side of the wafer was started, a processing time equivalent to a depth of 3.2 μm of the silicon substrate 9 was consumed. Since the etching of the silicon substrate 9 was continued on the outer peripheral side of the wafer as well, the depth of the first portions 17 on the outer peripheral side of the wafer reached 1.6 μm.

In order to form the first portions 17 over the entire wafer, it is necessary to secure a certain depth of the first portions 17 on the outer peripheral side of the wafer. For example, in the case of the Bosch process in which the silicon substrate 9 is etched by 0.8 μm per cycle, if the thickness of the silicon oxide film 10 is 0.5 μm, it is necessary to perform four cycles on the center side of the wafer and perform three cycles on the outer peripheral side of the wafer to remove the reaction by-products 41 and 42. In other words, the silicon substrate 9 is etched by 0.8 μm on the outer peripheral side of the wafer until the reaction by-product 42 is completely removed on the center side of the wafer. Therefore, in order to form the first portions 17 over the entire wafer, it is necessary to form the first portions 17 with a depth of at least 0.8 μm on the outer peripheral side of the wafer. In other words, it is desirable that each of the first portions 17 includes a portion that is 0.8 μm or more away from the contact surface between the silicon oxide film 10 and the silicon substrate 9.

The dimension T1 in the thickness direction X of each of the recesses 14 in the first portion 17 can be determined based on formation accuracy in an in-plane direction of the liquid discharge flow path 11. For example, when the formation accuracy in the in-plane direction of the liquid discharge flow path 11 is to be within 0.2 μm, a dimension T2 in the radial direction R of the recess 14 on one side may be set within 0.1 μm. Since the ratio of T1 to T2 is about 3, the dimension T1 of the recess 14 in the first portion 17 may be set to about 0.3 μm or less, and to be on the safe side, may be set to 0.25 μm or less.

Next, as illustrated in FIG. 6F, the Bosch process was continued with an increase in the output of the coil 34 from 2000 W to 2500 W and an increase in the time for etching from 0.6 seconds to 2.5 seconds (final cycle). The second portions 18 having second recesses 14B were formed over the entire area of the wafer. Then, although not illustrated, the Bosch process was continued under the same conditions to form the second through holes 13 having a depth of 20 μm. Then, the photoresist 16 was peeled off, whereby the discharge port formation substrate 3 illustrated in FIGS. 2A and 2B was obtained.

According to the present disclosure, it is possible to provide a laminated substrate with which it is possible to suppress variations in the width of holes in a silicon substrate at the boundary between the silicon substrate and a silicon oxide film.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-138348, filed Aug. 28, 2023, which is hereby incorporated by reference herein in its entirety.

What is claimed is:

1. A laminated substrate comprising:
a silicon substrate; and
a silicon oxide film laminated to the silicon substrate,
wherein the silicon oxide film has a through hole penetrating in a thickness direction,
wherein the silicon substrate has a hole communicating with the through hole,
wherein the hole includes a first portion adjacent to the through hole and a second portion adjacent to the first portion on an opposite side of the through hole,
wherein the first portion includes a plurality of first recesses whose width changes cyclically in the thickness direction,
wherein the second portion includes a plurality of second recesses whose width changes cyclically in the thickness direction, and
wherein a maximum value of the width of the first recesses is smaller than a maximum value of the width of the second recesses.

2. The laminated substrate according to claim 1, wherein the silicon oxide film has a contact surface in contact with the silicon substrate and a back surface of the contact surface, and a width of the through hole monotonically decreases from the back surface to the contact surface.

3. The laminated substrate according to claim 2, wherein an average inclination angle of a side surface of the through hole with respect to the contact surface is equal to or greater than 600 and less than 90°.

4. The laminated substrate according to claim 1, wherein the first portion includes a portion that is 0.8 m or more away from the contact surface between the silicon oxide film and the silicon substrate, and a length of each recess in the first portion in the thickness direction is 0.25 m or less.

5. The laminated substrate according to claim 1,
wherein the through hole is a first through hole, and
wherein the hole is a second through hole.

6. A liquid discharge head comprising:
a laminated substrate including a silicon substrate and a silicon oxide film laminated to the silicon substrate; and
an energy generation element,
wherein the silicon oxide film has a first through hole penetrating in a thickness direction,
wherein the silicon substrate has a second through hole communicating with the first through hole,
wherein the second through hole includes a first portion adjacent to the first through hole and a second portion adjacent to the first portion on an opposite side of the first through hole,
wherein the first portion includes a plurality of first recesses whose width changes cyclically in the thickness direction,
wherein the second portion includes a plurality of second recesses whose width changes cyclically in the thickness direction,
wherein a maximum value of the width of the first recesses is smaller than a maximum value of the width of the second recesses,
wherein the first through hole and the second through hole form a liquid discharge flow path through which a liquid is discharged, and
wherein the energy generation element imparts energy to the liquid to be discharged.

7. A manufacturing method for a laminated substrate, the method comprising:
forming a through hole penetrating in a thickness direction in a silicon oxide film laminated to a silicon substrate; and
forming a hole in the silicon substrate, the hole communicating with the through hole,
wherein the forming the hole includes forming a first portion adjacent to the through hole and forming a second portion adjacent to the first portion on an opposite side of the through hole after the forming the first portion,
wherein the first portion includes a plurality of first recesses whose width changes cyclically in the thickness direction,
wherein the second portion includes a plurality of second recesses whose width changes cyclically in the thickness direction, and
wherein a maximum value of the width of the first recesses is smaller than a maximum value of the width of the second recesses.

8. The manufacturing method for a laminated substrate according to claim 7, wherein the hole is formed by dry etching in which isotropic etching, formation of a sidewall protective film, and anisotropic etching are repeated, and in the forming the first portion, an amount of etching the silicon substrate per unit time is smaller than in the forming the second portion.

9. The manufacturing method for a laminated substrate according to claim 8, wherein the amount of etching the silicon substrate per unit time is reduced by at least one of reducing a time for dry etching per cycle, reducing output of a coil in an etching apparatus, and decreasing a pressure in a chamber.
